(19) United States
(12) Patent Application Publication
(10) Pub. No.: US 2026/0202438 A1
(43) Pub. Date: Jul. 16, 2026

(54) SOCKET SYSTEM TEST JIG AND METHODS

(71) Applicant: Amkor Technology Singapore Holding Pte. Ltd., Valley Point (SG)

(72) Inventor: Chun Ho JEONG, Incheon (KR)

(73) Assignee: Amkor Technology Singapore Holding Pte. Ltd., Valley Point (SG)

(21) Appl. No.: 19/019,059

(22) Filed: Jan. 13, 2025

(51) Int. Cl. G01R 1/04

(52) U.S. Cl. CPC G01R 1/0416

(57) ABSTRACT

In one example, a socket system test jig includes a pusher including, a pusher top side, a pusher lower side, and a through-hole extending through the pusher. The socket system test jig includes a cable assembly includes a cable including an inner conductor comprising an inner conductor first end and an inner conductor second end, a dielectric surrounding the inner conductor, and an outer conductor surrounding the dielectric and comprising an outer conductor first end and an outer conductor second end. In an implementation, the cable is through-coupled to the through-hole, the inner conductor first end is exposed from the pusher lower side, the outer conductor first end is exposed from the pusher lower side, and the outer conductor and the pusher lower side are electrically coupled. Other examples and related methods are also disclosed herein.

### CROSS REFERENCE TO RELATED APPLICATIONS

Not applicable.

### TECHNICAL FIELD

The present disclosure relates, in general, to a test jig, and more particularly, to a socket system test jig.

### BACKGROUND

Prior socket system test jigs are inadequate, for example resulting in excess cost, decreased reliability, relatively low performance, or socket system test jig sizes that are too large and complex. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIGS. 1A, 1B, 1C, and 1D are a side sectional view, a front sectional view, a plan view, and a bottom view, respectively, of an example socket system test jig.

FIGS. 2A, 2B, and 2C are a front sectional view, a side sectional view, and a plan view, respectively, of an example socket system test jig coupled to a socket on a board.

FIG. 2D is a schematic view showing the relationship between a cable assembly and a socket in an example socket system test jig.

FIG. 2E is a front sectional view of a device under test.

FIG. 3 is a cross-sectional view showing another example socket system test jig.

FIG. 4 is a cross-sectional view showing another example socket system test jig.

FIGS. 5A, 5B, 5C, 5D, 5E, and 5F are a perspective view, a side view, a front view, a back view, a plan view, and a bottom view, respectively, of a socket system test jig.

FIG. 5G is an enlarged bottom view of a pusher in an example socket system test jig.

FIG. 5H is a plan view showing the internal structure of an example socket system test jig.

FIGS. 6A and 6B are a side view and a perspective view showing an example socket system test jig coupled to a socket on a board.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and/or “including,” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements.

### DESCRIPTION

The present description includes, among other features, structures and associated methods that relate to electrical testing of electronic devices, such as RF electronic devices, high-speed digital electronic devices, or other devices requiring signal integrity validation. In some examples, the testing of Radio Frequency (RF) electronic devices and high-speed digital electronic devices require validation of an electrical test socket system before the electronic devices are tested. Such electronic devices can include but are not limited to fine-pitch ball grid array (BGA) type packages. In some examples, a test jig has been used for the validation. In some examples, the test socket and the system printed circuit board (PCB) are measured simultaneously as an in-situ measurement using the test jig. In some examples, both the magnitude and phase of the S-parameter of the test socket system are measured and this measurement requires, among other things, accuracy to avoid errors in subsequent test results and delays in testing cycle time. Previous approaches have been inadequate for several reasons, including, for example, accuracy at lower frequencies only (e.g., less than 6 to 8 GHz), complex structures, difficulties in making contact to pogo pins, contact to a limited number of ground pins (for examples, just two ground pins), which influences parasitics at the signal pin, poor return-loss performance, and limitations on the placement of signal pins.

Socket system test structures or jigs and related methods are described that address the issues set forth above as well as others. In some examples, the socket test jigs include an improved micro-coax pigtail that enhances socket measurements and that support fine-pitch BGA packaged electronic devices. The socket test jigs provide improved measurement accuracy compared to previous approaches, provide ground contact to a larger number of pogo pins, are cost effective, and are easier to fabricate. The socket test jigs support single-end, differential, and multiple port configurations. In addition, the socket test jigs of the present description improve RF performance including frequencies up to approximately 110 GHz.

In an example, a socket system test jig includes a pusher including, a pusher top side, a pusher lower side opposite to the pusher top side, and a through-hole extending through the pusher from the pusher top side to the pusher lower side. The socket system test jig includes a cable assembly includes a cable including an inner conductor comprising an inner conductor first end and an inner conductor second end opposite to the inner conductor first end, a dielectric surrounding the inner conductor, and an outer conductor surrounding the dielectric and comprising an outer conductor first end and an outer conductor second end opposite to the outer conductor first end. In an implementation, the cable is through-coupled to the through-hole, the inner conductor first end is exposed from the pusher lower side, the outer conductor first end is exposed from the pusher lower side, and the outer conductor and the pusher lower side are electrically coupled.

In an example, a socket system test jig includes a main body comprising a main body top side and a main body lower side opposite to the main body top side. A block body is coupled to the main body lower side. A pusher includes a pusher top side that is coupled to the main body lower side, a pusher lower side opposite to the pusher top side, and a through-hole extending through the pusher from the pusher top side to the pusher lower side. A cable assembly includes a connector and a cable. The cable includes an inner conductor including an inner conductor first end and an inner conductor second end opposite to the inner conductor first end, a dielectric surrounding the inner conductor, and an outer conductor surrounding the dielectric and comprising an outer conductor first end and an outer conductor second end opposite to the outer conductor first end. In an implementation, the pusher comprises a periphery, the cable is through-coupled to the through-hole, the inner conductor first end, the dielectric, and the outer conductor first end are exposed from the pusher lower side to form a socket pin contact, the cable is inside the main body, the connector is external to and coupled to the main body, the connector is coupled to the inner conductor second end and the outer conductor second end, and the block body surrounds the periphery of the pusher.

In an example, a method of testing a test socket system includes providing the test socket system including a board and a socket coupled to the board, wherein the socket includes a socket body comprising a bottom portion, side wall portions, and a recess extending inwardly to define the bottom portion, and a plurality of conductive pins extending through the bottom portion and coupled to the board, wherein the plurality of conductive pins are exposed from a top side of the bottom portion within the recess. The method includes providing a socket system test jig including a pusher including a pusher top side, a pusher lower side opposite to the pusher top side, and a through-hole extending through the pusher from the pusher top side to the pusher lower side; and a cable assembly including a cable with an inner conductor comprising an inner conductor first end and an inner conductor second end opposite to the inner conductor first end, a dielectric surrounding the inner conductor, and an outer conductor surrounding the dielectric and comprising an outer conductor first end and an outer conductor second end opposite to the outer conductor first end, wherein the cable is through-coupled to the through-hole and the inner conductor first end, the dielectric, and the outer conductor first end are exposed from the pusher lower side to form a socket pin contact. The method includes coupling the socket system test jig to the socket so that the pusher is within the recess of the socket body, the inner conductor first end is coupled to a first conductive pin of the plurality of conductive pins, and the outer conductor first end is coupled to a second conductive pin and a third conductive pin of the plurality of conductive pins. The method includes providing electrical measurements of the test socket system using the socket system test jig.

Other examples are included in the present disclosure. Such examples may be found in the figures, in the claims, or in the description of the present disclosure.

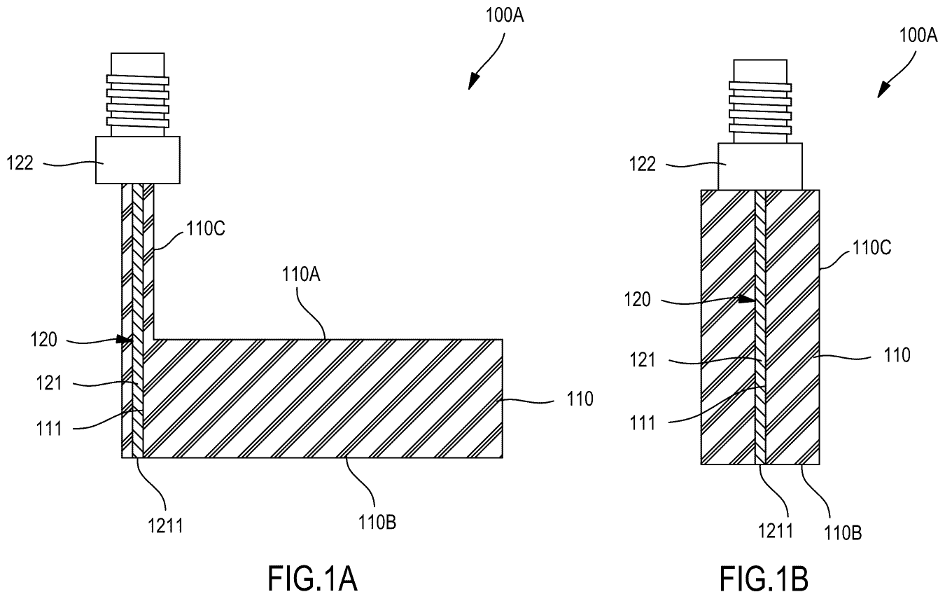

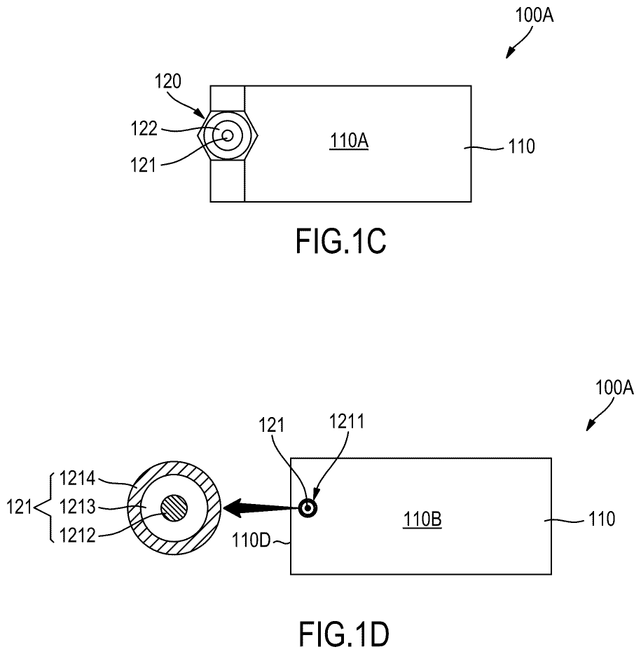

FIGS. 1A, 1B, 1C, and 1D are a side sectional view, a front sectional view, a plan view, and a bottom view, respectively, of an example socket system test jig 100A in accordance with the present description. In the example shown in FIGS. 1A to 1D, socket system test jig 100A can comprise pusher 110 and cable assembly 120. Socket system test jig 100A can also comprise or be referred to as a socket system test jig structure, a socket system test jig apparatus, a socket system test structure, or a socket system test apparatus.

In some examples, pusher 110 can comprise a hexahedron shape, such as cube shape or a shape that mates with the test socket that socket system test jig 100A is configured to test. Pusher 110 can comprise through-hole 111 on one side for coupling cable assembly 120, a pusher top side 110A and a pusher lower side opposite to pusher top side 110A. In some examples, pusher 110 can comprise an appendage 110C extending upward from pusher top side 110A and through-hole 111 can extend upward through appendage 110C. In some examples, pusher 110 can be provided without appendage 110C.

In some examples, the diameter of through-hole 111 can range from approximately 0.5 millimeter (mm) to approximately 1.5 mm depending on the cable diameter of cable assembly 120. In some examples, pusher 110 can be formed of a conductor such as metal. In some examples, the thickness of pusher 110 can range from approximately 5 mm to approximately 20 mm depending on the depth of socket, and the width of pusher 110 can range from approximately 2 mm to approximately 50 mm depending on the size of an actual device mounted in the socket. Pusher 110 can be configured to detachably attach to the electrical test socket system, which can include a socket or test socket attached to a board or test board, such as PCB. Pusher 110 can comprise or be referred to as a block, a test block, or a test body.

In some examples, cable assembly 120 can comprise cable 121 and connector 122. Cable 121 can be within or through-coupled to through-hole 111 of pusher 110. In some examples, cable 121 can pass through from pusher top side 110A to pusher lower side 110B, and the lower end of cable 121 can be exposed or protrude through or be exposed from pusher lower side 110B. In some examples, connector 122 can be positioned or mounted on pusher top side 110A of pusher 110, including, for example, the top of appendage 110C. The lower end of cable 121 that is exposed from or protruding through pusher lower side 110B (which includes inner conductor 1212 first end, dielectric 1213, and outer conductor 1214 first end) can comprise and be referred to as pogo pin contact 1211. Pogo pin contact 1211 can comprise or be referred to as a test contact or a socket pin contact. In some examples, pogo pin contact 1211 and pusher lower side 110B can be substantially coplanar. Cable assembly 120 can comprise and be referred to as an RF pigtail or a micro-coax pigtail. Cable 121 can comprise and be referred to as a semi-rigid or rigid coax cable or a micro-coax cable.

In some examples and with reference to FIG. 1D, cable 121 can comprise inner conductor 1212, dielectric 1213 surrounding inner conductor 1212, and outer conductor 1214 surrounding dielectric 1213. Inner conductor 1212 comprises an inner conductor first end exposed from pusher lower side 110B and an inner conductor second end opposite to the inner conductor first end and coupled to connector 122. Outer conductor 1214 comprises an outer conductor first end exposed from pusher lower side 110B and an outer conductor second end opposite the outer conductor first end and coupled to connector 122. In some examples, inner conductor 1212 can comprise copper, aluminum, nickel, palladium, gold, silver, steel, silver-plated copper wire clad steel, or other materials known to one of ordinary skill in the art. In some examples, inner conductor 1212 is placed proximate to an edge 110D of pusher lower side 110B.

In some examples, the diameter of inner conductor 1212 can range from approximately 0.1 mm to approximately 0.5 mm. In some examples, inner conductor 1212 is configured as or comprises a signal pin or signal line. In some examples, dielectric 1213 can comprise an insulating resin such as polyethylene (PE), polytetrafluoroethylene (PTFE), fluorinated ethylene propylene (FEP) or other insulating materials known to one of ordinary skill in the art. In some examples, the diameter of dielectric 1213 can range from approximately 0.4 mm to approximately 1 mm. In some examples, outer conductor 1214 can comprise copper, aluminum, nickel, palladium, gold, silver, steel, or similar material known to one of ordinary skill in the art. In some examples, the diameter of outer conductor 1214 can range from approximately 0.5 mm to approximately 1.2 mm and can be configured as or comprises a ground pin or ground line. In some examples, outer conductor 1214 is electrically coupled to pusher lower side 110B so that pusher lower side 110B can provide a ground plane configured to contact and ground a larger number of pogo pins in the test socket compared to previous jig designs.

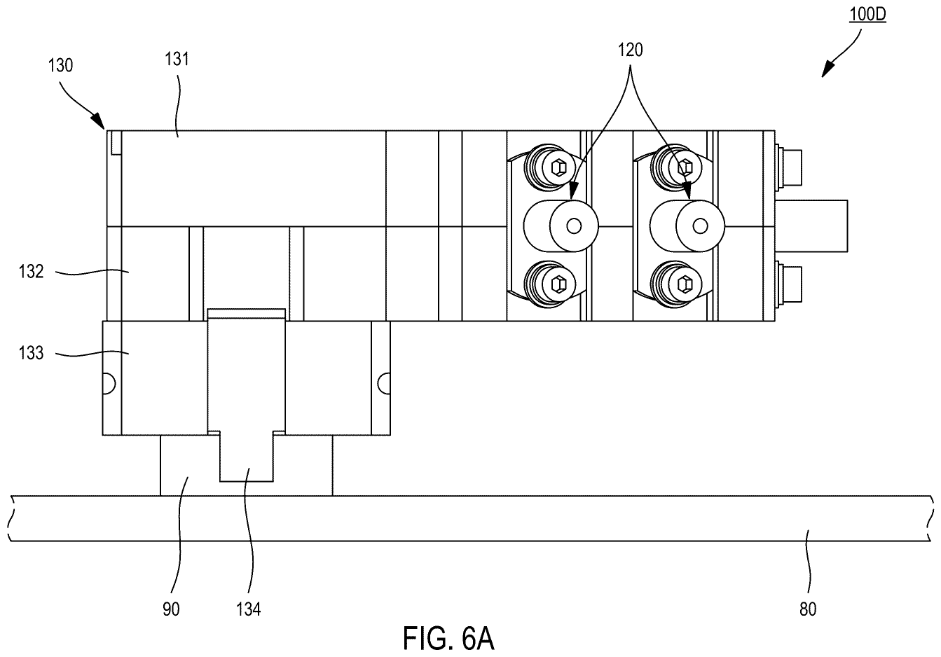

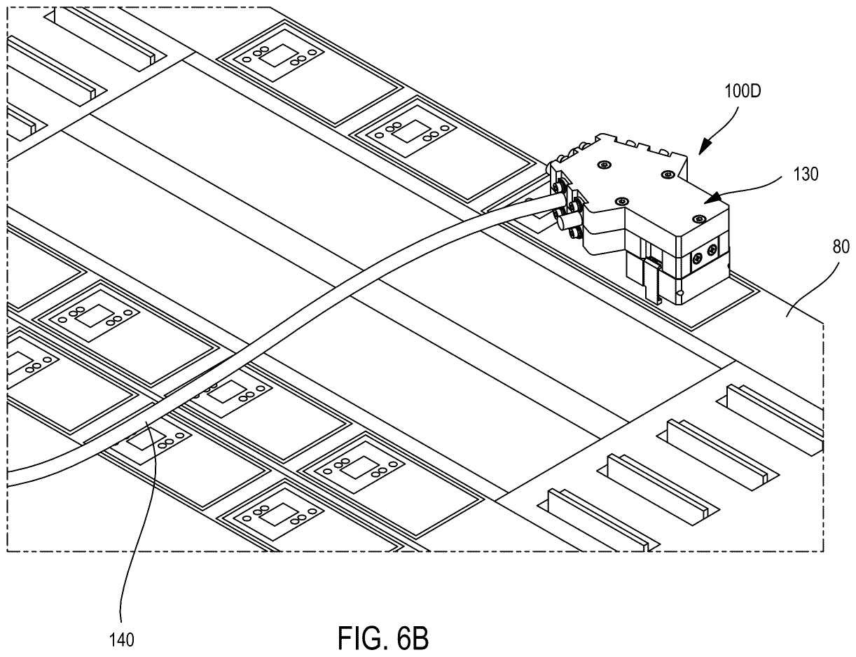

The length of cable 121 can be set to various values depending on the application. The specifications of connector 122 can be set to various values depending on the measurement frequency band and application. Generally, the shorter the length of cable 121 the better to minimize signal loss. In some examples, the length of cable 121 can be in a range from about 15 mm to about 100 mm. Connector 122 can be electrically connected to an external test device through a test cable (for example, test cable 140 illustrated in FIG. 6B), thereby electrically connecting cable 121 and the test device to each other. Although connector 122 is shown as threaded-type connector, other types of connector configurations including high-frequency connectors can be used. In some examples, connector 122 is selected in accordance with the target test frequency. In some examples, a 2.92 mm connector can be used for frequencies up to about 40 GHz. In other examples, 1 mm connector can be used for frequencies up to about 77 GHz.

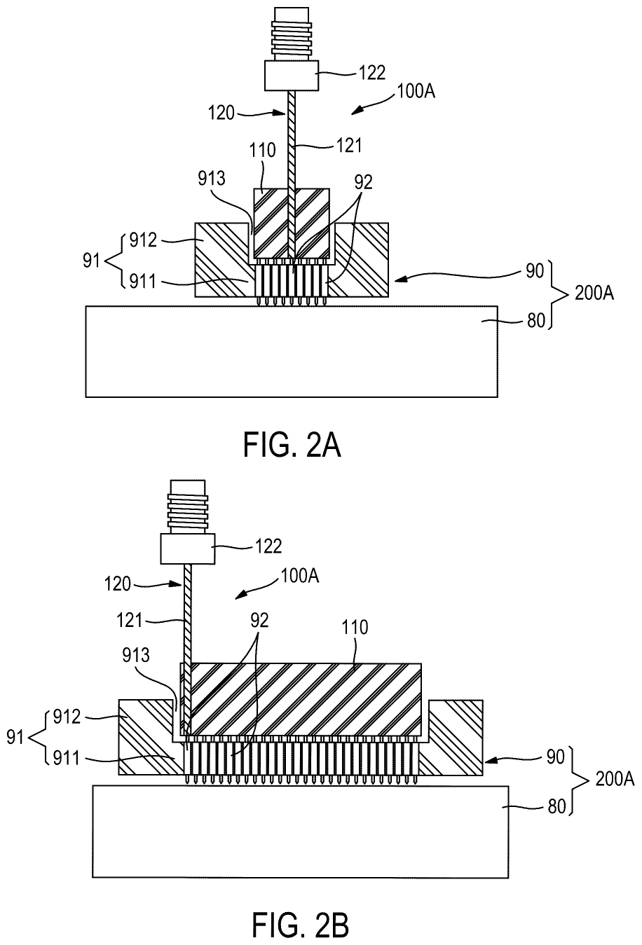

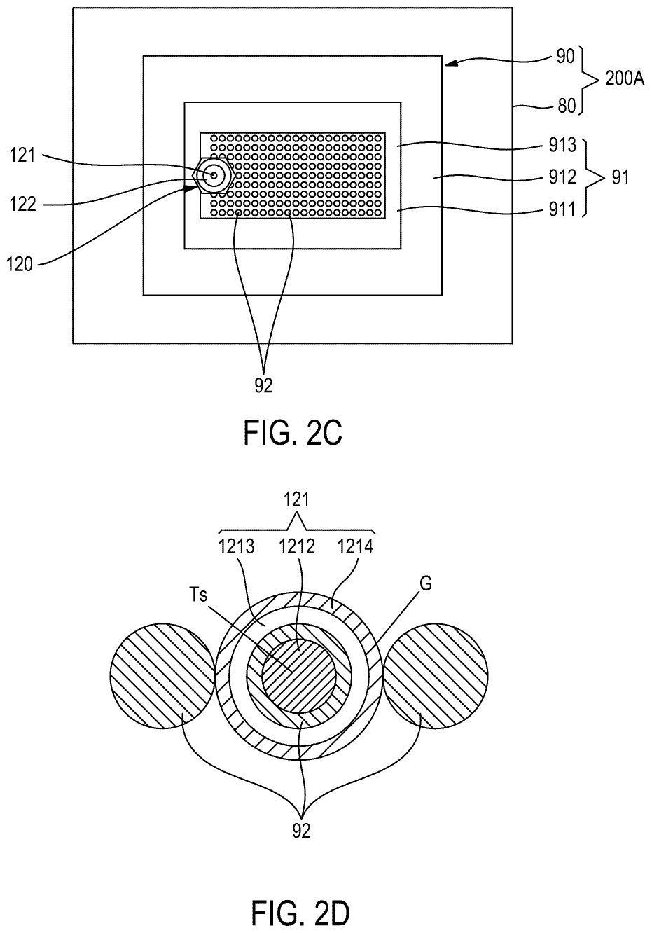

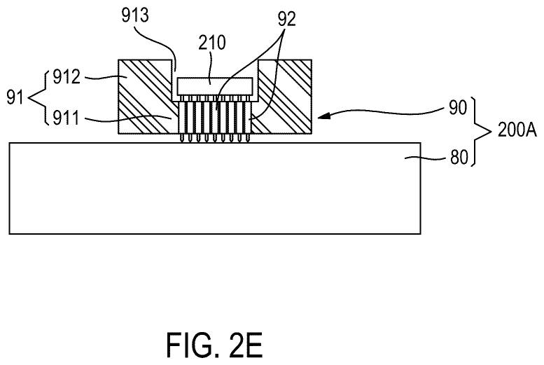

FIGS. 2A, 2B, and 2C show a front sectional view, a side sectional view, and a plan view, respectively, of example socket system test jig 100A coupled to an electrical test socket system 200A comprising socket 90 on board 80. In the example shown in FIGS. 2A to 2C, socket system test jig 100A can be electrically coupled to socket 90 on board 80 as part of a method of validating socket 90 in preparation of electrical testing of the electronic devices. In some examples, electrical test socket system 200A comprising socket 90 on board 80 can be provided and socket system test jig 100A can be provided as part of the method. Board 80 can comprise or be referred to as a load board.

In general, test socket 90 acts as an intermediary or intermediate structure so that an electronic device can be connected to an external test device, which sends and receives electrical signals to and from the electronic device. Test socket 90 is configured to provide an effective interface between the electronic device, board 80, and the test system. Test socket 90 facilitates the transmission of electrical signals between the electronic device and the board (ATE system), which allows the board (ATE system) to measure the electrical characteristics of the electronic device. Since some electronic devices, such as RF electronic devices operate at very high frequencies, test socket 90 is configured to effectively operate at such frequencies and to minimize signal distortion or loss.

In some examples, socket 90 can comprise socket body 91 and multiple or a plurality of pogo pins 92 coupled to socket body 91. In some examples, socket body 91 can comprise a rectangular box shape comprising an open top. In some examples, socket body 91 can comprise bottom portion 911 and side wall portions 912, and a recess 913 extending inwardly to define bottom portion 911 and side wall portions 912. In some examples, socket body 91 can be made of an engineering plastic, polymer, ceramic or other materials having high heat resistance and high insulative characteristics. In some examples, the height of side wall portions 912 of socket body 91 can range from approximately 5 mm to approximately 20 mm and the thickness of bottom portion 911 of socket body 91 can range from approximately 1 mm to approximately 10 mm. In some examples, pogo pins 92 extend through bottom portion 911 and are exposed from the lower side of socket 90 and exposed from a top side of bottom portion 911. Pogo pins 92 can comprise or be referred to conductive pins or conductive spring pins.

Socket 90 can be electrically connected to board 80 through pogo pins 92, and during the validation test of socket 90 with board 80 in accordance with the present method, pusher 110 of socket system test jig 100A can be coupled to socket 90 so that pogo pin contact 1211 makes electrical contact to one or more of pogo pins 92 in socket body 91.

Multiple pogo pins 92 can be coupled through bottom portion 911 of test socket 90, the upper ends of pogo pins 92 can be exposed or protrude upwardly through bottom portion 911 of socket body 91, and the lower ends of pogo pins 92 can protrude downwardly through bottom portion 911 to be electrically coupled to board 80. In some examples, pogo pins 92 can have rows and columns and can be arranged in a matrix shape on bottom portion 911. In some examples, pogo pins 92 can comprise gold-plated beryllium copper or gold-plated stainless steel having high electrical conductivity and excellent spring properties. In some examples, the lengths of pogo pins 92 can range from approximately 1 mm to approximately 10 mm. Pogo pins 92 can electrically connect cable assembly 120 of socket system test jig 100A to board 80.

During the test step of the present method, pusher 110 of socket system test jig 100A can be coupled to or within recess 913 of socket body 91. As will be described below, pusher 110 can comprise a locking device, such as a locking pin or a locking lever, coupled to socket 90 so that pusher 110 can be firmly and securely coupled to test socket 90. Cable assembly 120 coupled to pusher 110 can be in electrical contact with one of multiple pogo pins 92. In some examples, inner conductor 1212 of cable 121 of cable assembly 120 can be in electrical contact with one of pogo pins 92 and outer conductor 1214 can be in electrical contact with one or more other pogo pins 92.

FIG. 2D is a schematic view showing the relationship between cable assembly 120 and socket 90 in example socket system test jig 100A. In the example shown in FIG. 2D, inner conductor 1212 of cable 121 can be in electrical contact with one of pogo pins 92 provided in socket 90, and outer conductor 1214 of cable 121 can be in electrical contact with the other two of multiple pogo pins 92 provided in socket 90. For example, inner conductor 1212 can be a signal line, and outer conductor 1214 can be a ground line. Pogo pin 92 in contact with inner conductor 1212 can transmit a signal and pogo pin(s) 92 in contact with outer conductor 1214 can be grounded. Pusher lower side 110B can be in contact with other of pogo pins 92 and can be grounded through contact with outer conductor 1214. In some examples, inner conductor 1212 is coupled to receive a test signal (Ts) from a test device and outer conductor 1214 is coupled to ground (G). During a validation test of socket 90 and board 80, one or more test signals (Ts) are provided to inner conductor 1212 and electrical measurements are taken to validate socket 90 and board 80 in-situ in accordance with the present description.

FIG. 2E is a front sectional view showing a device under test (DUT) 210 after socket system test jig 100A has been used to validate socket 90 and board 80. DUT 210 can be one of a plurality of devices under test. DUT 210 is an example of electronic device, and in accordance with the present method, the electronic device is coupled to socket test system 200A and tested after the validation step.

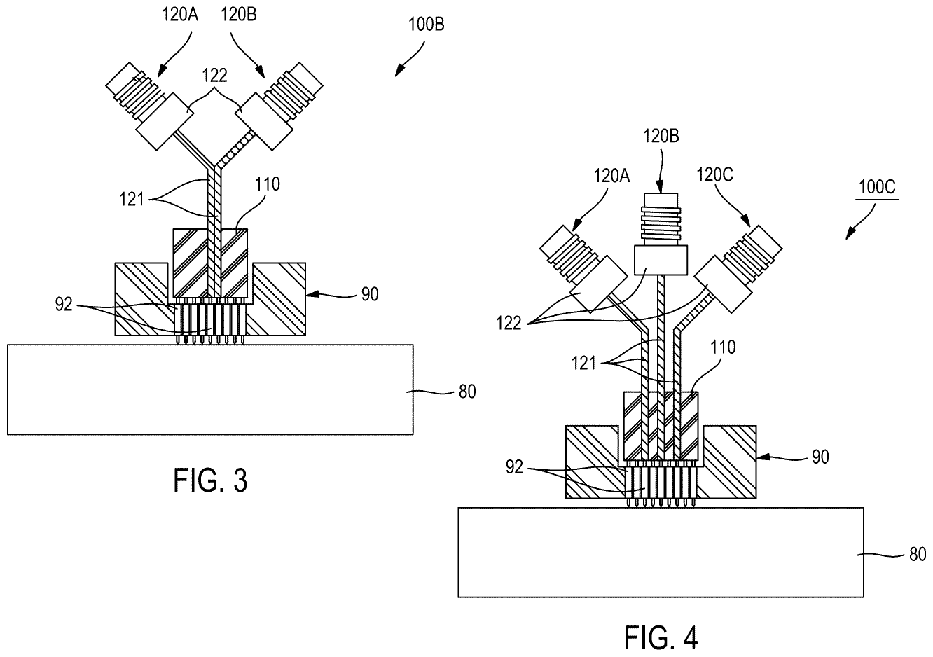

FIG. 3 is a cross-sectional view showing another example socket system test jig 100B. As shown in FIG. 3, socket system test jig 100B can have at least two cable assemblies 120 coupled to one pusher 110. For example, a first cable assembly 120A can be in electrical contact with a first one of pogo pins 92, and a second cable assembly 120B can be in electrical contact with a second one of pogo pins 92. In some examples, second cable assembly 120B comprises a second cable comprising a second inner conductor, which can be similar to inner conductor 1212, a second dielectric that surrounds the second inner conductor, which can be similar to dielectric 1213, and a second outer conductor that surrounds the second dielectric, which can be similar to outer conductor 1214. In some examples, the second cable assembly can comprise a second connector, which can be similar to connector 122.

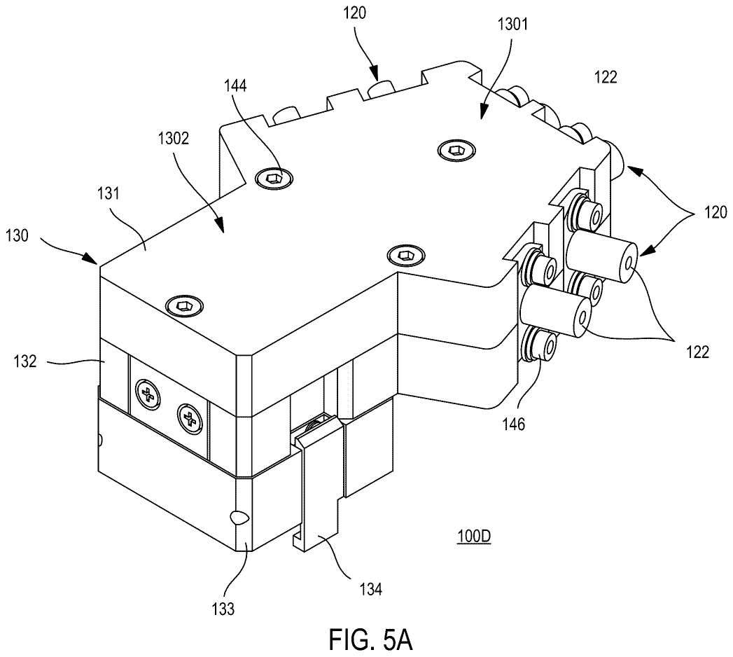

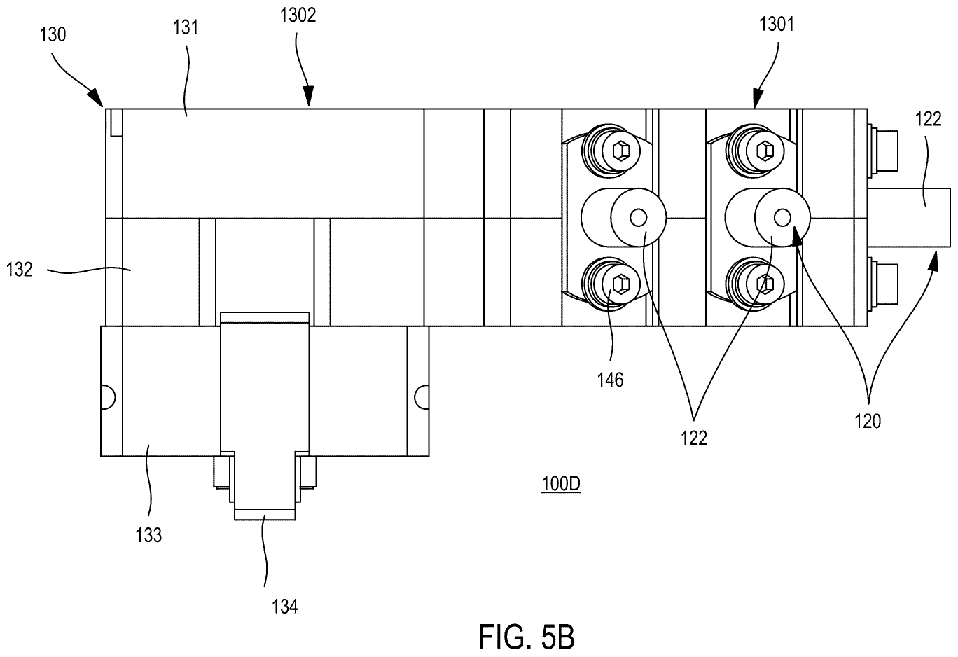

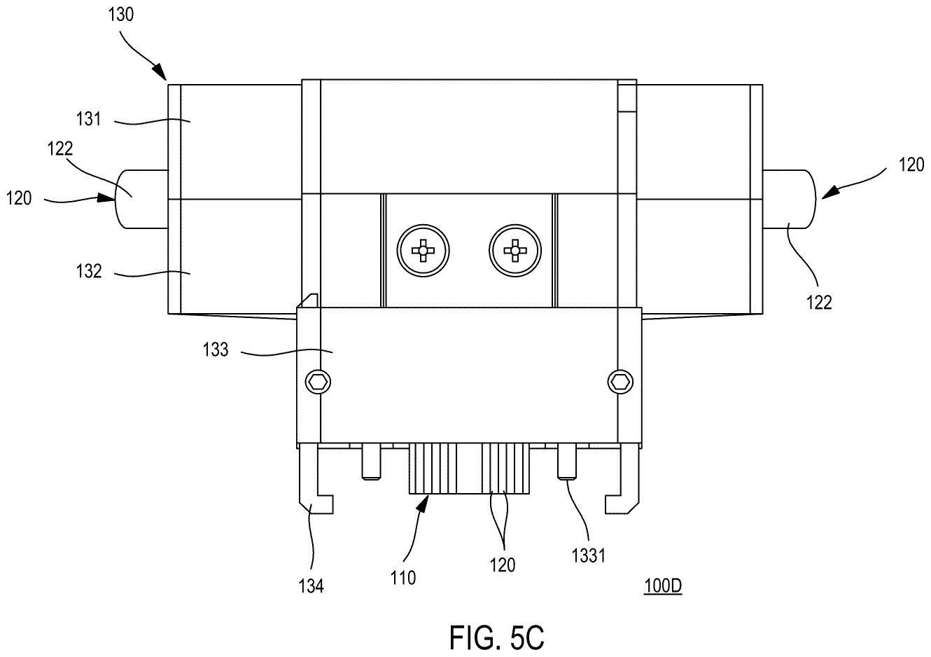

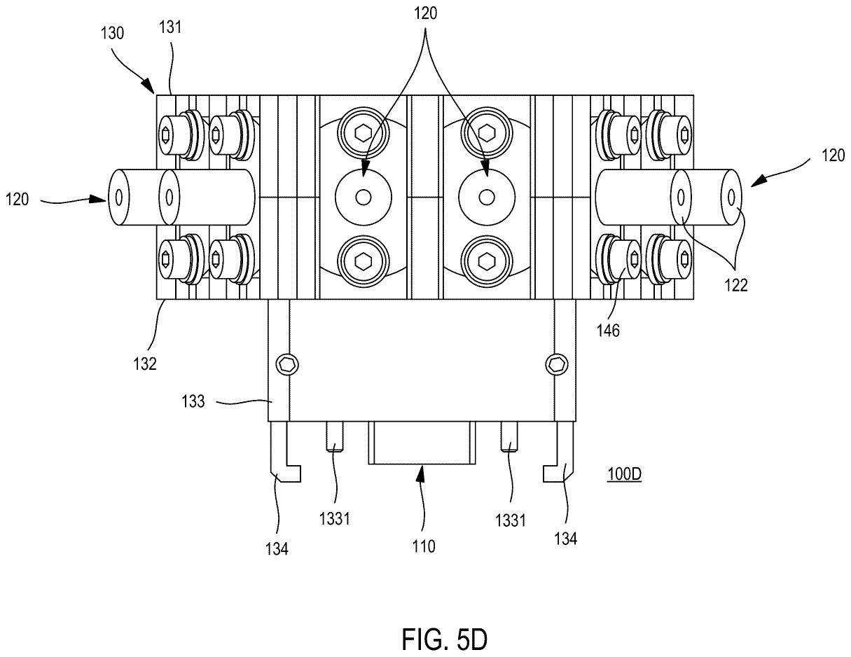

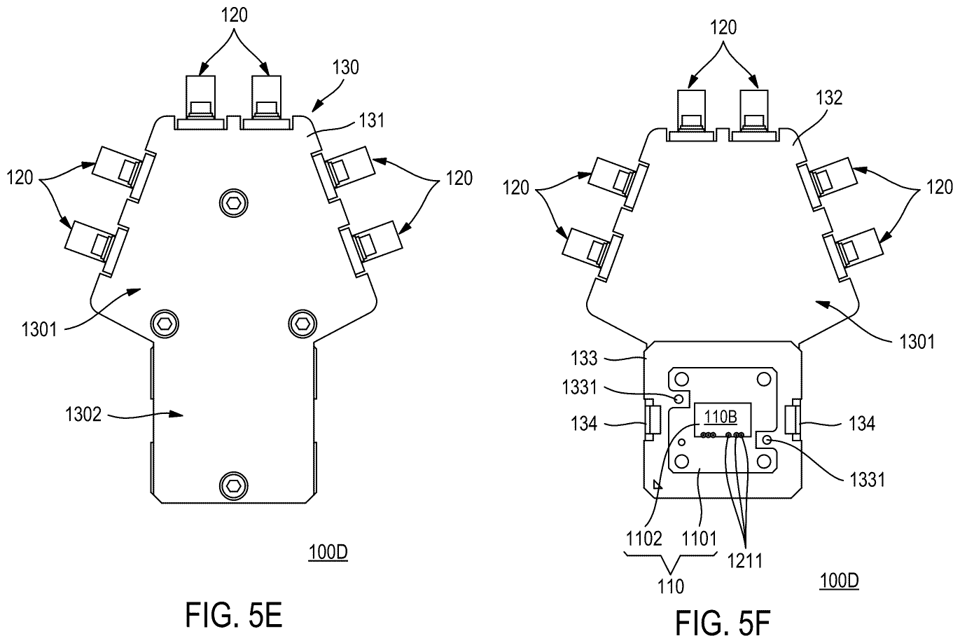

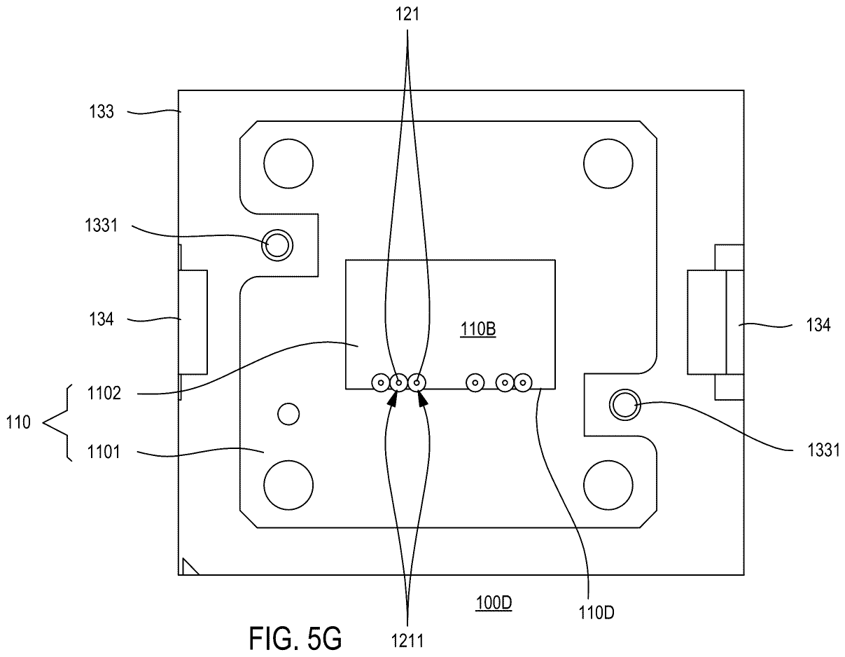

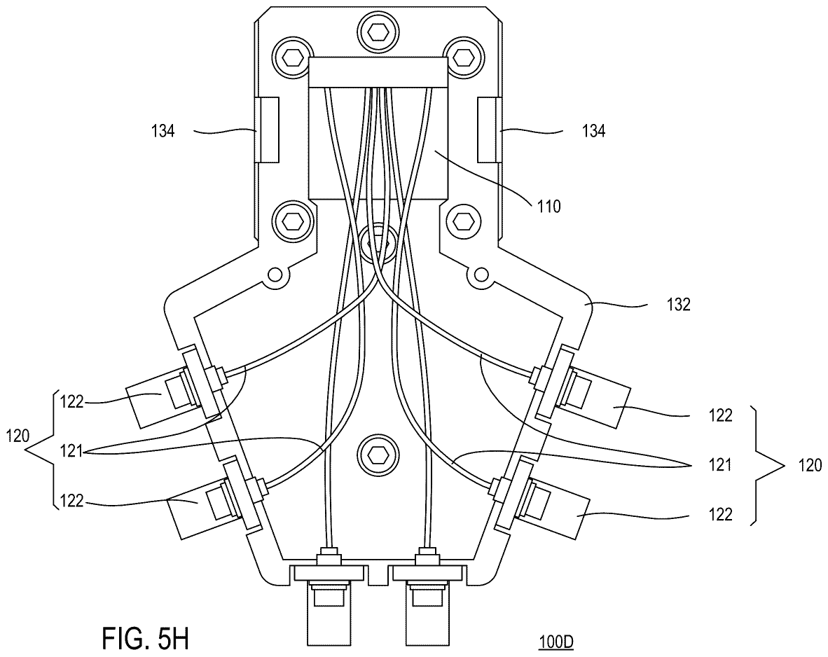

In some examples, the second cable is through-coupled to a second through-hole extending through pusher 110 from pusher top side 110A to pusher lower side 110B. The second inner conductor can comprise a second inner conductor first end and a second inner conductor second end opposite to the second inner conductor first end and the second outer conductor can comprise a second outer conductor first end and a second outer conductor second end opposite to the outer conductor first end. In some examples, the second inner conductor first end is exposed from the pusher lower side, the second outer conductor first end is exposed from the pusher lower side; and the second outer conductor and the pusher lower side are electrically coupled. In some examples, inner conductor 1212 and the second inner conductor can be placed proximate to the same edge of pusher lower side 110B (for example, edge 110D shown in FIG. 1D or FIG. 5G) and can be laterally spaced apart. The placement of the inner conductors can correspond to where the signal pogo pins are in the socket to be tested.

FIG. 4 is a cross-sectional view showing another example socket system test jig 100C. As shown in FIG. 4, in socket system test jig 100C, at least three cable assemblies 120 can be coupled to one pusher 110. For example, first cable assembly 120A can be in electrical contact with a first one of pogo pins 92, second cable assembly 120B can be in electrical contact with a second one pogo pins 92, and a third cable assembly 120C can be in electrical contact a third one of pogo pins 92. In some examples, third cable assembly 120C comprises a third cable comprising a third inner conductor, which can be similar to inner conductor 1212, a third dielectric that surrounds the third inner conductor, which can be similar to dielectric 1213, and a third outer conductor that surrounds the third dielectric, which can be similar to outer conductor 1214. In some examples, the third cable assembly can comprise a third connector, which can be similar to or different than connector 122.

In some examples, the third cable is through-coupled to a third through-hole extending through pusher 110 from pusher top side 110A to pusher lower side 110B. The third inner conductor can comprise a third inner conductor first end and a third inner conductor second end opposite to the third inner conductor first end and the third outer conductor can comprise a third outer conductor first end and a third outer conductor second end opposite to the outer conductor first end. In some examples, the third inner conductor first end is exposed from the pusher lower side, the third outer conductor first end is exposed from the pusher lower side; and the third outer conductor and the pusher lower side are electrically coupled. In some examples, inner conductor 1212, the second inner conductor, and the third inner conductor can be placed proximate to the same edge of pusher lower side 110B (for example, edge 110D shown in FIG. 1D or FIG. 5G) and can be laterally spaced apart. The placement of the inner conductors can correspond to where the signal pogo pins are in the socket to be tested.

With reference to both FIG. 3 and FIG. 4, the second connector can be coupled to the second inner conductor second end and the second outer conductor second end, and with reference to FIG. 4, the third connector can be coupled to the third inner conductor second end and the third outer conductor second end. The second cable assembly or the third cable assembly can comprise and be referred to as RF pigtails or micro-coax pigtails. The second cable or the third cable can comprise and be referred to as a semi-rigid or rigid coax cable or a micro-coax cable.

Next, a socket system test jig 100D comprising pusher 110 and cable assembly 120 similar or identical to those described above will be described. The socket system test jig 100D is another example for understanding the present disclosure and can be modified in various ways depending on the design of board 80 or socket 90.

FIGS. 5A, 5B, 5C, 5D, 5E, and 5F are a perspective view, a side view, a front view, a back view, a plan view, and a bottom view, respectively, of socket system test jig 100D. As shown in FIGS. 5A to 5F, socket system test jig 100D can comprise pusher 110, cable assembly 120, and main block 130. Here, since pusher 110 and cable assembly 120 have already been described above, main block 130 will be mainly described. Main block 130 can be provided in various shapes depending on the shapes or features of board 80 and socket 90.

In some examples, main block 130 can comprise top cover 131, bottom cover 132, block body 133, and lever 134. In some examples, top cover 131 can define a main block top side or a housing top side and bottom cover 132 can define a main block lower side or a housing lower side, which is opposite to the main block top side. Cable assembly 120 can be coupled between top cover 131 and bottom cover 132. Main block 130 can comprise or be referred to as a housing or an enclosure. Lever 134 can comprise or be referred to as a clip, a clamp, or a clamping bracket.

In some examples, top cover 131 and bottom cover 132 can comprise rear region 1301 having approximately five sides and front region 1302 having approximately three sides. In some examples, rear region 1301 can comprise a hexagonal shape, but other shapes can be used. In some examples, front region 1302 can comprise a square shape, but other shapes can be used. Top cover 131 and bottom cover 132 can be coupled to each other, for example, through multiple bolts 144 penetrating top cover 131 and bottom cover 132.

In some examples, connector 122 of cable assembly 120 can be coupled to rear region 1301 of top cover 131 and bottom cover 132 using fasteners 146. In some examples, a first set of two cable assemblies 120 with connectors 122 can be coupled to a first side of rear region 1301, a second set of two cable assemblies 120 with connectors 122 can be coupled to a second side of rear region 1301, and a third set of cable assemblies with connectors 122 can be coupled to a third side of rear region 1301. In some examples, the second side is opposite to the first side and third side connects the first side to the second side.

In some examples, top cover 131 and bottom cover 132 can comprise metal, ceramic, or plastic. In some examples, top cover 131 and bottom cover 132 can comprise copper, aluminum, nickel, palladium, gold, silver, or steel. In some examples, the thicknesses of top cover 131 and bottom cover 132 can range from approximately 5 mm to approximately 20 mm, and the widths of top cover 131 and bottom cover 132 can range from approximately 10 mm to approximately 50 mm. In some examples, cable 121 is enclosed within top cover 131 and bottom cover 132. Top cover 131 and bottom cover 132 protect cable assembly 120 from external environments and couple together and support pusher 110 and block body 133.

In some examples, pusher 110 can be coupled to front region 1302 of top cover 131 and bottom cover 132. In some examples, pusher 110 can be coupled to the lower surface of bottom cover 132. In some examples, pusher 110 can be coupled to bottom cover 132 by a fixing member including a spring and a bolt. By providing an opening in an area of bottom cover 132 corresponding to pusher 110, cable 121 can penetrate bottom cover 132 to be through-coupled to pusher 110.

Block body 133 can be coupled to bottom cover 132 and can surround the periphery of pusher 110. Pusher 110 can be exposed from the exterior side (e.g., the lower side) through block body 133. Block body 133 can comprise locking pin 1331 provided on and extending downwardly from the lower surface of block body 133. The height of locking pin 1331 protruding from block body 133 can range from approximately 2 mm to approximately 10 mm. Locking pin 1331 can prevent pusher 110 from moving in the horizontal direction during the test process when block body 133 is coupled to socket 90. The thickness of block body 133 can be similar to that of pusher 110. Block body 133 can protect the side portion of pusher 110 from external environments. Lever 134 can be coupled to opposite sides of block body 133. In some examples, lever 134 can have a horizontal rotation axis and can be rotatably coupled to block body 133, and a spring can be interposed between the upper side of lever 134 and block body 133. Lever 134 can be configured to clamp to socket 90 to constrain movement of pusher 110 in the vertical direction during the test process when block body 133 is coupled to socket 90. Lever 134 can comprise or be referred to as a clamp structure or a reversible locking structure.

FIG. 5G is an enlarged bottom view of pusher 110 in example socket system test jig 100D. As shown in FIG. 5G, pusher 110 can comprise pusher body 1101 and pusher protrusion 1102 protruding outward or downward from pusher body 1101. in some examples, pusher protrusion 1102 includes pusher lower side 110B. Cable 121 of cable assembly 120 can penetrate pusher protrusion 1102. Multiple pogo pin contacts 1211 can be provided in pusher protrusion 1102 exposed from pusher lower side 110B. The thickness of pusher protrusion 1102 protruding from pusher body 1101 can be similar to the depth of socket 90 (e.g., the depth of recess 913 provided in socket 90). As described above, block body 133 can surround pusher 110, and block body 133 can have locking pins 1331 provided on opposite sides to be coupled to socket 90.

FIG. 5H is a top plan view showing the internal structure of example socket system test jig 100D. In the example shown in FIG. 5H, top cover 131 can be removed from bottom cover 132. Cable assembly 120 can comprise connector 122 and cable 121. connector 122 can be coupled between top cover 131 and bottom cover 132, and cable 121 can extend from connector 122 to be through-coupled to pusher 110. Cable 121 can comprise or be referred to as a micro-coax cable or a pigtail.

FIGS. 6A and 6B are a side view and a perspective view showing example socket system test jig 100D coupled to socket 90 on board 80. In the example shown in FIGS. 6A and 6B, socket system test jig 100D can be coupled to socket 90 on board 80. Pusher 110 of socket system test jig 100D can be coupled to the interior side (e.g., recess 913) of socket 90 and lever 134 can be coupled to the exterior side of socket 90. The test device and socket system test jig 100D can be connected to each other by test cable 140. In some examples, the test device can include a vector network analyzer, a signal (spectrum) analyzer, a signal generator, or a power meter. One end of the test cable 140 can be electrically connected to connector 122 of socket system test jig 100D, and the other end of test cable 140 can be electrically connected to the test device.

Socket system test jigs 100A, 100B, 100C, and 100D according to the present disclosure can verify the overall RF performance by subjecting board 80 (e.g., an actual system board) and socket 90 to simultaneous measurement in-situ. The socket system test jig according to the present disclosure can be simplified in structure, and thus the cost can be reduced and better RF performance (for example, up to 110 GHz is possible with a 1 mm RF connector) can be provided. The socket system test jigs according to the present disclosure can be used for signal integrity analysis of a test socket in a high-speed digital system. In the socket system test jigs according to the present disclosure, high-quality micro-coax cables (e.g., pigtails) can be used for socket measurements because mechanical dimensions are well suited to fine-pitch BGA patterns.

In summary, socket system test structures or jigs and related methods have been described that address the issues highlighted herein with previous test jig designs. In some examples, the socket test jigs include an improved micro-coax pigtail that enhances socket measurements and that support fine-pitch BGA packaged electronic devices. The socket test jigs provide improved measurement accuracy compared to previous approaches, provide ground contact to a larger number of pogo pins, are cost effective, and are easier to fabricate. The socket test jigs support single-end, differential, and multiple port configurations. In addition, the socket test jigs of the present description improve RF performance including frequencies up to approximately 110 GHz.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure is not limited to the examples disclosed, but that the disclosure will include all examples falling within the scope of the appended claims.

What is claimed is:

1. A socket system test jig, comprising:
a pusher comprising:
a pusher top side;
a pusher lower side opposite to the pusher top side; and
a through-hole extending through the pusher from the pusher top side to the pusher lower side; and
a cable assembly comprising:
a cable comprising:
an inner conductor comprising an inner conductor first end and an inner conductor second end opposite to the inner conductor first end;
a dielectric surrounding the inner conductor; and
an outer conductor surrounding the dielectric and comprising an outer conductor first end and an outer conductor second end opposite to the outer conductor first end;
wherein:
the cable is through-coupled to the through-hole;
the inner conductor first end is exposed from the pusher lower side;
the outer conductor first end is exposed from the pusher lower side; and
the outer conductor and the pusher lower side are electrically coupled.

2. The socket system test jig of claim 1, wherein:
the cable assembly comprises a connector coupled to the inner conductor second end and the outer conductor second end.

3. The socket system test jig of claim 1, wherein:
the inner conductor comprises a signal line; and
the outer conductor comprises a ground line.

4. The socket system test jig of claim 1, wherein:
the pusher lower side comprises a ground plane.

5. The socket system test jig of claim 1, further comprising:
a second cable assembly comprising:
a second cable comprising:
a second inner conductor comprising a second inner conductor first end and a second inner conductor second end opposite to the second inner conductor first end;
a second dielectric surrounding the second inner conductor; and
a second outer conductor surrounding the second dielectric and comprising a second outer conductor first end and a second outer conductor second end opposite to the outer conductor first end;
wherein:
the pusher comprises a second through-hole extending from the pusher top side to the pusher lower side;
the second cable is through-coupled to the second through-hole;
the second inner conductor first end is exposed from the pusher lower side;
the second outer conductor first end is exposed from the pusher lower side; and
the second outer conductor and the pusher lower side are electrically coupled.

6. The socket system test jig of claim 1, wherein:
the inner conductor comprises a diameter in a range from approximately 0.1 millimeter (mm) to approximately 0.5 mm.

7. The socket system test jig of claim 1, further comprising:
a connector; and
a main block comprising:
a top cover;
a bottom cover coupled to the top cover; and
a block body;
wherein:
the top cover and the bottom cover comprise a rear region and a front region;
the cable is enclosed within the top cover and the bottom cover;
the block body is coupled to the bottom cover in the front region;
the connector is coupled to the cable and the main block within the rear region;
the pusher is coupled to the bottom cover in the front region; and
the block body surrounds a periphery of the pusher.

8. The socket system test jig of claim 7, further comprising:
a locking pin protruding downward from the block body.

9. The socket system test jig of claim 7, further comprising:
a clamp structure rotatably coupled to the block body.

10. The socket system test jig of claim 7, wherein:
the pusher comprises a pusher body and a pusher protrusion protruding outward from the pusher body; and
the pusher protrusion includes the pusher lower side.

11. The socket system test jig of claim 1, wherein:
the inner conductor first end, the dielectric, and the outer conductor first end comprise a socket pin contact; and
the socket pin contact and the pusher lower side are substantially coplanar.

12. A socket system test jig, comprising:
a main body comprising a main body top side and a main body lower side opposite to the main body top side;
a block body coupled to the main body lower side;
a pusher comprising:
a pusher top side coupled to the main body lower side;
a pusher lower side opposite to the pusher top side; and
a through-hole extending through the pusher from the pusher top side to the pusher lower side; and
a cable assembly comprising:
a connector; and
a cable comprising:
an inner conductor comprising an inner conductor first end and an inner conductor second end opposite to the inner conductor first end;
a dielectric surrounding the inner conductor; and
an outer conductor surrounding the dielectric and comprising an outer conductor first end and an outer conductor second end opposite to the outer conductor first end;
wherein:
the pusher comprises a periphery;
the cable is through-coupled to the through-hole;
the inner conductor first end, the dielectric, and the outer conductor first end are exposed from the pusher lower side to form a socket pin contact;
the cable is inside the main body;
the connector is external to and coupled to the main body;
the connector is coupled to the inner conductor second end and the outer conductor second end; and
the block body surrounds the periphery of the pusher.

13. The socket system test jig of claim 12, wherein:
the outer conductor and the pusher lower side are electrically coupled.

14. The socket system test jig of claim 12, further comprising:
a locking pin protruding downward from the block body.

15. The socket system test jig of claim 12, further comprising:
a clamp structure rotatably coupled to the block body.

16. The socket system test jig of claim 12, wherein:
the pusher comprises a pusher body and a pusher protrusion protruding outward from the pusher body; and
the pusher protrusion includes the pusher lower side.

17. The socket system test jig of claim 12, wherein:
the inner conductor first end, the dielectric, and the outer conductor first end provide a socket pin contact; and
the socket pin contact and the pusher lower side are substantially coplanar.

18. A method of testing a test socket system, comprising:
providing the test socket system comprising:
a board; and
a socket coupled to the board and comprising:
a socket body comprising a bottom portion, side wall portions, and a recess extending inwardly to define the bottom portion; and
a plurality of conductive pins extending through the bottom portion and coupled to the board, wherein the plurality of conductive pins are exposed from a top side of the bottom portion within the recess;
providing a socket system test jig comprising:
a pusher comprising:
a pusher top side;
a pusher lower side opposite to the pusher top side; and
a through-hole extending through the pusher from the pusher top side to the pusher lower side; and
a cable assembly comprising:
a cable comprising:
an inner conductor comprising an inner conductor first end and an inner conductor second end opposite to the inner conductor first end;
a dielectric surrounding the inner conductor; and
an outer conductor surrounding the dielectric and comprising an outer conductor first end and an outer conductor second end opposite to the outer conductor first end;
wherein:
the cable is through-coupled to the through-hole; and
the inner conductor first end, the dielectric, and the outer conductor first end are exposed from the pusher lower side to form a socket pin contact;
coupling the socket system test jig to the socket so that the pusher is within the recess of the socket body, the inner conductor first end is coupled to a first conductive pin of the plurality of conductive pins, and the outer conductor first end is coupled to a second conductive pin and a third conductive pin of the plurality of conductive pins; and
providing electrical measurements of the test socket system using the socket system test jig.

19. The method of claim 18, wherein:
the outer conductor is coupled to the pusher lower side;
coupling the socket system test jig comprise coupling the pusher lower side to other ones of the plurality of conductive pins;
providing the electrical measurements comprises:
coupling the outer conductor to a ground signal; and
providing a test signal to the inner conductor; and
the method further comprises:
removing the socket system test jig;
coupling an electronic device to the test socket system; and
testing the electronic device.

20. The method of claim 18, wherein providing the socket system test jig comprises:
providing a connector; and
providing a main block comprising:
a top cover;
a bottom cover coupled to the top cover; and
a block body;
wherein:
the top cover and the bottom cover comprise a rear region and a front region;
the cable is enclosed within the top cover and the bottom cover;
the block body is coupled to the bottom cover in the front region;
the connector is coupled to the cable and the main block within the rear region;
the pusher is coupled to the bottom cover in the front region; and
the block body surrounds a periphery of the pusher.
